(19) United States
(12) Patent Application Publication
(10) Pub. No.: US 2022/0102662 A1
(43) Pub. Date: Mar. 31, 2022

(54) LIGHT EMITTING DEVICE, DISPLAY SUBSTRATE AND DISPLAY EQUIPMENT

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Han NIE, Beijing (CN); Xunfei TONG, Beijing (CN); Min DENG, Beijing (CN); Xiaokun LIANG, Beijing (CN); Dongyu GAO, Beijing (CN); Ganghu LIU, Beijing (CN); Huihui LI, Beijing (CN); Peng FENG, Beijing (CN)

(73) Assignees: CHENGDU BOE OPTOELECTRONICS TECHNOLOGY CO., LTD., Chengdu (CN); BOE TECHNOLOGY GROUP CO., LTD., Beijing (CN)

(21) Appl. No.: 17/307,324

(22) Filed: May 4, 2021

(30) Foreign Application Priority Data
Sep. 27, 2020 (CN) 202011032167.8

(51) Int. Cl. H01L 51/50; C09K 11/06

(52) U.S. Cl. CPC H01L 51/5028; H01L 51/0072; C09K 11/06

(57) ABSTRACT

The present disclosure provides a light emitting device, a display substrate and a display equipment. The light emitting device includes: a light emitting layer, the light emitting layer including a host material including an aggregation-induced delayed fluorescent material and a guest material including at least one of a fluorescent material or a phosphorescent material.

### CROSS-REFERENCE TO RELATED APPLICATION

This application claims priority to Chinese Patent Application No. 202011032167.8 filed on Sep. 27, 2020, which is incorporated herein by reference in its entirety.

### TECHNICAL FIELD

The present disclosure relates to the field of display technology, in particular, to a light emitting device, a display substrate and a display equipment.

### BACKGROUND

Organic light emitting diodes (OLED) have gradually become a new generation of mainstream display technology. Device efficiency is one of the key factors that determine the overall performance of the product. The high manufacturing cost of the device has always been the main bottleneck restricting the large-scale commercialization.

### SUMMARY

In one aspect, an embodiment of the present disclosure provides a light emitting device, including: a light emitting layer, the light emitting layer including a host material including an aggregation-induced delayed fluorescent material and a guest material including at least one of a fluorescent material or a phosphorescent material.

In an example, an emission spectrum of the host material at least partially overlaps an absorption spectrum of the guest material.

In an example, a content of the guest material is in a range from 0.3% to 1% of a sum of masses of the host material and the guest material.

In an example, the host material includes at least one of CP-BP-DMAC, DBT-BZ-DMAC, DCB-BP-PXZ, CBP-BP-PXZ, mCP-BP-PXZ, mCBP-BP-PXZ, PCZ-CB-TRZ or TPA-CB-TRZ; and the guest material includes at least one of Ir(ppy)₃, PO-1, Ir(MDQ)₂acac, TTPA, TBRb or DBP;

in which CP-BP-DMAC has a structural formula of:

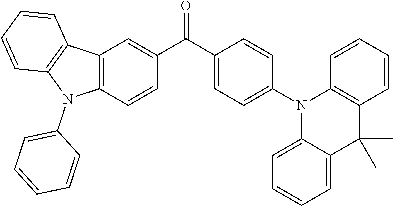 [SMILES: CC1(C)c2ccccc2N(c2ccc(C(=O)c3ccc4c(c3)c3ccccc3n4-c3ccccc3)cc2)c2ccccc21]

DBT-BZ-DMAC has a structural formula of:

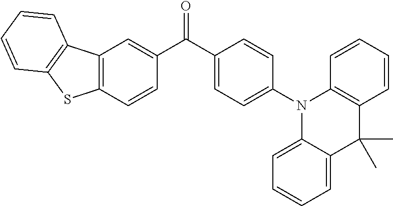 [SMILES: CC1(C)c2ccccc2N(c2ccc(C(=O)c3ccc4sc5ccccc5c4c3)cc2)c2ccccc21]

DCB-BP-PXZ has a structural formula of:

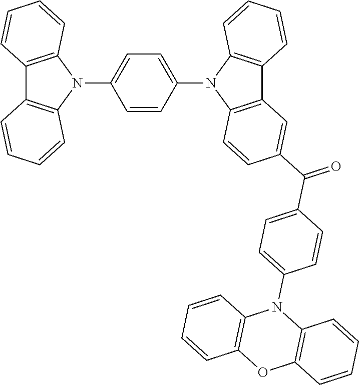 [SMILES: O=C(c1ccc(N2c3ccccc3Oc3ccccc32)cc1)c1ccc2c(c1)c1ccccc1n2-c1ccc(-n2c3ccccc3c3ccccc32)cc1]

DCB-BP-PXZ has a structural formula of:

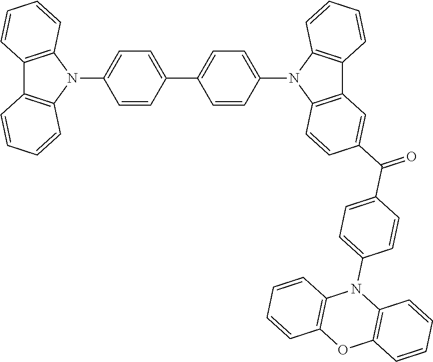 [SMILES: O=C(c1ccc(N2c3ccccc3Oc3ccccc32)cc1)c1ccc2c(c1)c1ccccc1n2-c1ccc(-c2ccc(-n3c4ccccc4c4ccccc43)cc2)cc1]

mCP-BP-PXZ has a structural formula of:

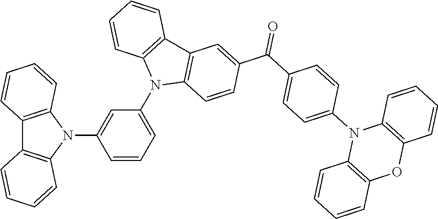 [SMILES: O=C(c1ccc(N2c3ccccc3Oc3ccccc32)cc1)c1ccc2c(c1)c1ccccc1n2-c1cccc(-n2c3ccccc3c3ccccc32)c1]

mCBP-BP-PXZ has a structural formula of:

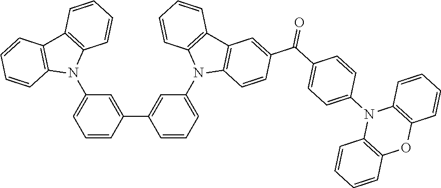 [SMILES: O=C(c1ccc(N2c3ccccc3Oc3ccccc32)cc1)c1ccc2c(c1)c1ccccc1n2-c1cccc(-c2cccc(-n3c4ccccc4c4ccccc43)c2)c1]

PCZ-CB-TRZ has a structural formula of:

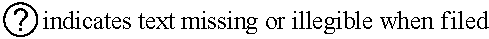

TPA-CB-TRZ has a structural formula of:

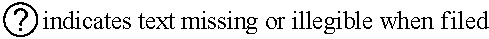

Ir(ppy)₃ has a structural formula of:

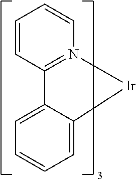

PO-1 has a structural formula of:

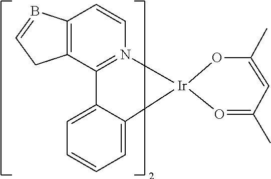

Ir(MDQ)₂acac has a structural formula of:

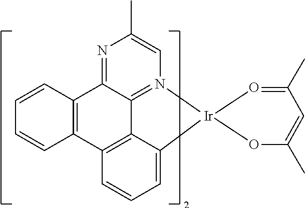

TTPA has a structural formula of:

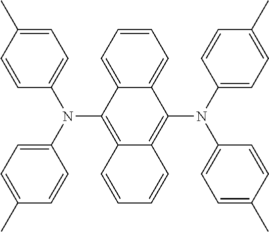 [SMILES: Cc1ccc(N(c2ccc(C)cc2)c2c3ccccc3c(N(c3ccc(C)cc3)c3ccc(C)cc3)c3ccccc23)cc1]

TBRb has a structural formula of:

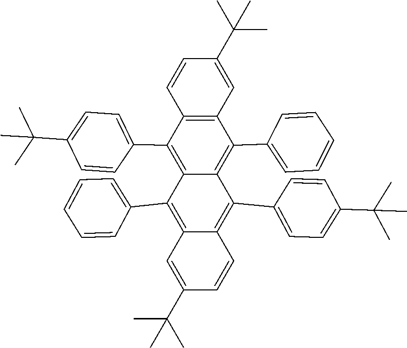 [SMILES: CC(C)(C)c1ccc(-c2c3ccc(C(C)(C)C)cc3c(-c3ccccc3)c3c(-c4ccc(C(C)(C)C)cc4)c4ccc(C(C)(C)C)cc4c(-c4ccccc4)c23)cc1]

DBP has a structural formula of:

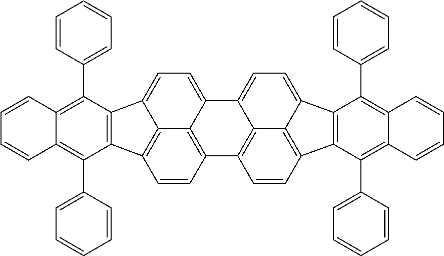 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]

in which signs “•” in the structural formulae of PCZ-CB-TRZ and TPA-CB-TRZ represent BH.

In an example, the host material is CP-BP-DMAC or DBT-BZ-DMAC, and the guest material is Ir(ppy)₃.

In an example, the host material is CP-BP-DMAC or DBT-BZ-DMAC, and the guest material is PO-1.

In an example, the host material is DCB-BP-PXZ, CBP-BP-PXZ, mCP-BP-PXZ or mCBP-BP-PXZ, and the guest material is Ir(MDQ)₂acac.

In an example, the host material is CP-BP-DMAC or DBT-BZ-DMAC, and the guest material is TTPA.

In an example, the host material is PCZ-CB-TRZ or TPA-CB-TRZ, and the guest material is DBP.

In an example, the host material is DCB-BP-PXZ, CBP-BP-PXZ, mCP-BP-PXZ or mCBP-BP-PXZ, and the guest material is TBRb.

In one example, the light emitting device includes: a hole transport layer and an electron transport layer, in which the hole transport layer, the light emitting layer, and the electron transport layer are stacked in sequence.

In one example, the light emitting device further includes: a hole injection layer and an electron injection layer, in which the hole injection layer, the hole transport layer, the light emitting layer, the electron transport layer, and the electron injection layer are stacked in sequence.

In one example, the light emitting device further includes: an anode and a cathode, in which the anode, the hole transport layer, the light emitting layer, the electron transport layer, and the cathode are stacked in sequence.

In a second aspect, an embodiment of the present disclosure provides a display substrate, including the light emitting device as described in the above embodiment.

In a third aspect, an embodiment of the present disclosure provides a display equipment, including the display substrate as described in the above embodiment.

### BRIEF DESCRIPTION OF THE DRAWINGS

FIG. 1a is a schematic view showing a light emitting device according to an embodiment of the present disclosure;

FIG. 1b is a schematic view showing a light emitting device according to another embodiment of the present disclosure;

FIG. 2 is a principle schematic view showing a phosphorescent device having a traditional host material;

FIG. 3 is a principle schematic view showing a phosphorescent device having TADF as the host material;

FIG. 4 is a principle schematic view showing a light emitting device having AIDF as the host material according to the present disclosure;

FIG. 5 is a schematic view showing a spectrum of an AIDF host material and a TTPA material;

FIG. 6 is a schematic view showing a spectrum of a different AIDF host material and a TBRb material;

FIG. 7 is a schematic view showing a spectrum of a different AIDF host material and a DBP materials;

FIG. 8 is a principle schematic view showing a light emitting device having TADF as the host material; and

FIG. 9 is a principle schematic view showing a light emitting device having AIDF as a host material.

### DETAILED DESCRIPTION

In order to illustrate the purposes, technical solution and advantages in the embodiments of the present disclosure in a clearer manner, the technical solutions in the embodiments of the present disclosure will be described hereinafter in conjunction with the drawings in the embodiments of the present disclosure in a clear and complete manner. Obviously, the following embodiments relate to a part of, rather than all of, the embodiments of the present disclosure. Based on the described embodiments of the present disclosure, a person skilled in the art may obtain the other embodiments, which also fall within the scope of the present disclosure.

The light emitting device according to the embodiment of the present disclosure will be described in detail below.

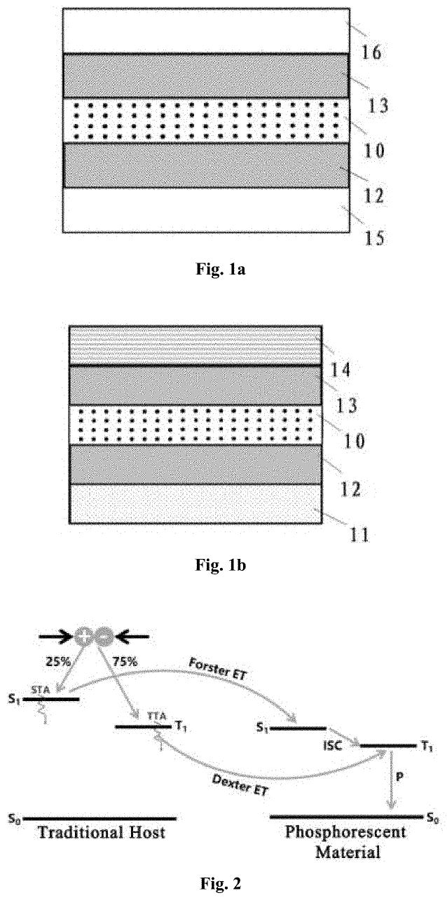

As shown in FIGS. 1a and 1b, the light emitting device according to an embodiment of the present disclosure includes: a light emitting layer 10, having a host material including an aggregation-induced delayed fluorescent material and a guest material including at least one of a fluorescent material and/or a phosphorescent material.

That is to say, the light emitting device is mainly composed of the light emitting layer 10, in which the light emitting layer 10 has a host material including an aggregation-induced delayed fluorescent (AIDF) material and a guest material including at least one of a fluorescent material and/or a phosphorescent material. For example, the guest material is a fluorescent material or a phosphorescent material. In the light emitting device of the present disclosure, the aggregation-induced delayed fluorescent material is used as the host material, at least one of the fluorescent material and/or phosphorescent material is used as the doped light emitting material, and the triplet excitons on the aggregation-induced delayed fluorescent material can form singlet excitons by virtue of the upconversion in the process of the reverse intersystem crossing. At the same time, due to the weak intermolecular force thereof, the aggregation-induced delayed fluorescent material can effectively inhibit the exciton annihilation process, improve the luminous efficiency, prolong the lifetime, and reduce the cost.

Among them, an emission spectrum of the host material at least partially overlaps an absorption spectrum of the guest material, so as to effectively promote energy transfer and improve luminous efficiency.

Optionally, a content of the guest material is in a range from 0.3% to 1% of the sum of masses of the host material and the guest material, and the doping concentration of the guest material is low and can be reduced to less than 1%, thereby greatly reducing the cost.

In some embodiments of the present disclosure, the host material may include at least one of CP-BP-DMAC, DBT-BZ-DMAC, DCB-BP-PXZ, CBP-BP-PXZ, mCP-BP-PXZ, mCBP-BP-PXZ, PCZ-CB-TRZ and TPA-CB-TRZ; and the guest material may include at least one of Ir(ppy)₃, PO-1, Ir(MDQ)₂acac, TTPA, TBRb and DBP;

in which CP-BP-DMAC has a structural formula of:

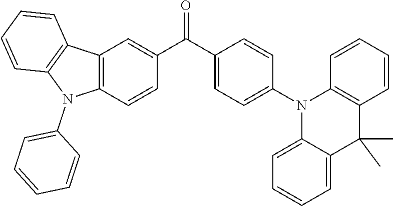 [SMILES: CC1(C)c2ccccc2N(c2ccc(C(=O)c3ccc4c(c3)c3ccccc3n4-c3ccccc3)cc2)c2ccccc21]

DBT-BZ-DMAC has a structural formula of:

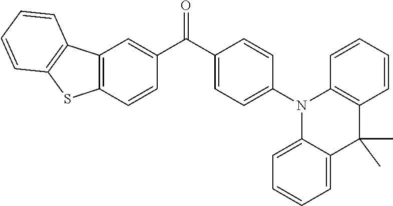 [SMILES: CC1(C)c2ccccc2N(c2ccc(C(=O)c3ccc4sc5ccccc5c4c3)cc2)c2ccccc21]

DCB-BP-PXZ has a structural formula of:

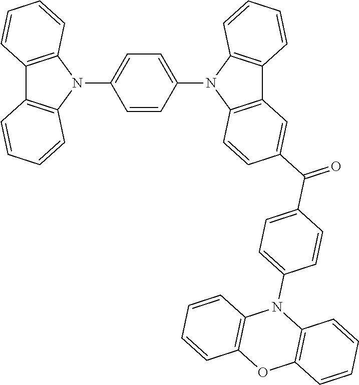 [SMILES: O=C(c1ccc(N2c3ccccc3Oc3ccccc32)cc1)c1ccc2c(c1)c1ccccc1n2-c1ccc(-n2c3ccccc3c3ccccc32)cc1]

CBP-BP-PXZ has a structural formula of:

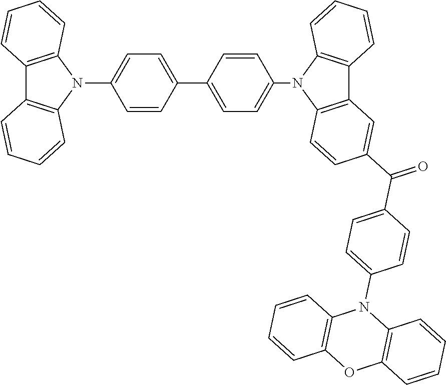 [SMILES: O=C(c1ccc(N2c3ccccc3Oc3ccccc32)cc1)c1ccc2c(c1)c1ccccc1n2-c1ccc(-c2ccc(-n3c4ccccc4c4ccccc43)cc2)cc1]

mCP-BP-PXZ has a structural formula of:

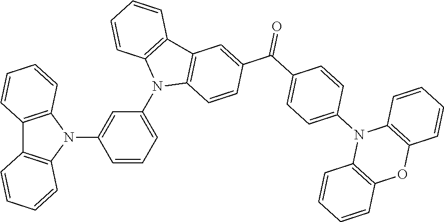 [SMILES: O=C(c1ccc(N2c3ccccc3Oc3ccccc32)cc1)c1ccc2c(c1)c1ccccc1n2-c1cccc(-n2c3ccccc3c3ccccc32)c1]

mCBP-BP-PXZ has a structural formula of:

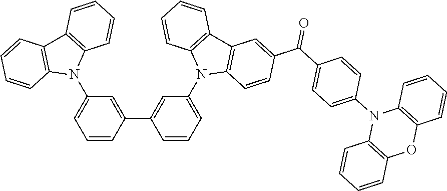 [SMILES: O=C(c1ccc(N2c3ccccc3Oc3ccccc32)cc1)c1ccc2c(c1)c1ccccc1n2-c1cccc(-c2cccc(-n3c4ccccc4c4ccccc43)c2)c1]

Ir(ppy)₃ has a structural formula of:

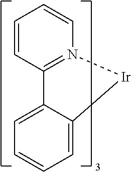

PO-1 has a structural formula of:

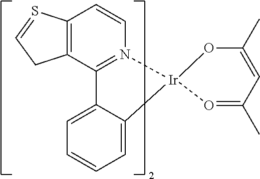

Ir(MDQ)₂acac has a structural formula of:

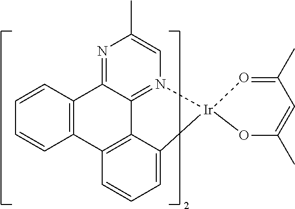

PCZ-CB-TRZ has a structural formula of:

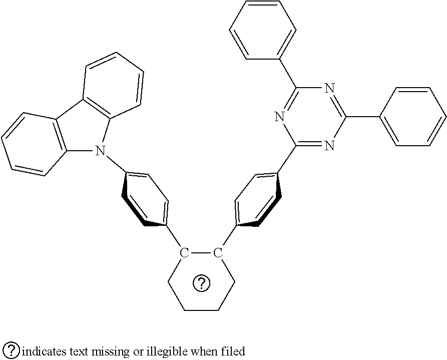

TPA-CB-TRZ has a structural formula of:

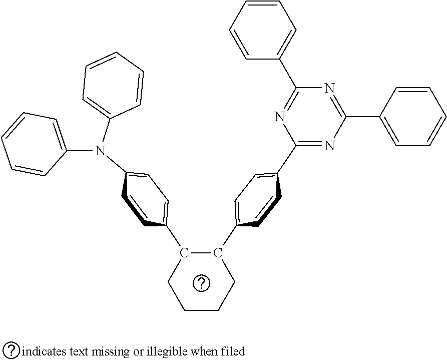

TTPA has a structural formula of:

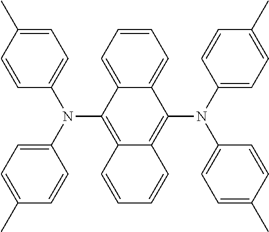 [SMILES: Cc1ccc(N(c2ccc(C)cc2)c2c3ccccc3c(N(c3ccc(C)cc3)c3ccc(C)cc3)c3ccccc23)cc1]

TBRb has a structural formula of:

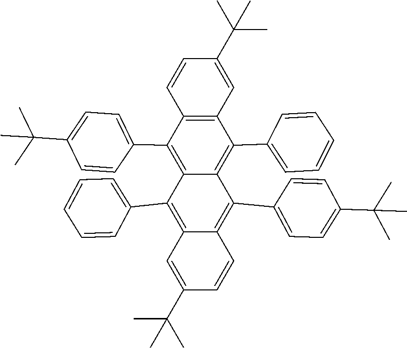 [SMILES: CC(C)(C)c1ccc(-c2c3ccc(C(C)(C)C)cc3c(-c3ccccc3)c3c(-c4ccc(C(C)(C)C)cc4)c4ccc(C(C)(C)C)cc4c(-c4ccccc4)c23)cc1]

DBP has a structural formula of:

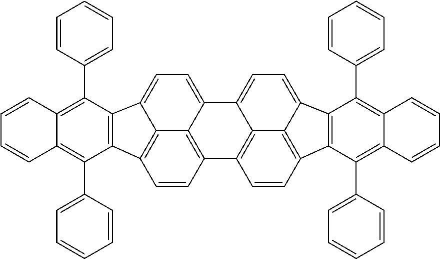 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]

in which signs “•” in the structural formulae of PCZ-CB-TRZ and TPA-CB-TRZ represent BH. In the application process, the host material and the guest material can be reasonably selected according to actual needs, so that the light emitting layer has higher luminous efficiency and long lifetime, and reduce the cost at the same time.

In some embodiments, the host material may be CP-BP-DMAC or DBT-BZ-DMAC, and the guest material may be Ir(ppy)₃. Among them, CP-BP-DMAC and DBT-BZ-DMAC are typical AIDF materials, which have T₁→S₁ upconversion characteristics, their non-doped OLED devices have high efficiency and low roll-off, and using CP-BP-DMAC and DBT-BZ-DMAC as the host material can effectively inhibit exciton annihilation. Ir(ppy)₃ is a green phosphorescent material, the emission energy of CP-BP-DMAC and DBT-BZ-DMAC is 2.5 eV, and the absorption band gap width (gap) of Ir(ppy)₃ is 2.4 eV. Thus, using CP-BP-DMAC or DBT-BZ-DMAC as the host material of Ir(ppy)₃ can effectively promote energy transfer. Therefore, using CP-BP-DMAC or DBT-BZ-DMAC as the host material and Ir(ppy)₃ as the guest material can realize a green light emitting device having high efficiency and low cost.

In other embodiments, the host material may be CP-BP-DMAC or DBT-BZ-DMAC and the guest material may be PO-1; among them, CP-BP-DMAC and DBT-BZ-DMAC are AIDF materials, which have T₁→S₁ upconversion characteristics, and their non-doped OLED devices have high efficiency and low roll-off, thereby effectively inhibiting exciton annihilation. PO-1 is a yellow phosphorescent material, the emission energy of CP-BP-DMAC and DBT-BZ-DMAC is 2.5 eV, and the absorption band gap width (gap) of PO-1 is 2.4 eV. Thus, using CP-BP-DMAC or DBT-BZ-DMAC as the host material of PO-1 can effectively promote energy transfer. Therefore, using CP-BP-DMAC or DBT-BZ-DMAC as the host material and PO-1 as the guest material can realize a yellow light emitting device having high efficiency and low cost.

In an embodiment of the present disclosure, the host material may be DCB-BP-PXZ, CBP-BP-PXZ, mCP-BP-PXZ or mCBP-BP-PXZ, and the guest material may be Ir(MDQ)₂acac. Among them, DCB-BP-PXZ, CBP-BP-PXZ, mCP-BP-PXZ or mCBP-BP-PXZ are AIDF materials, which have T₁→S₁ upconversion characteristics, and their non-doped OLED devices have high efficiency and low roll-off, thereby effectively inhibiting exciton annihilation. Ir(MDQ)₂acac is a red phosphorescent material, the emission energy of DCB-BP-PXZ, CBP-BP-PXZ, mCP-BP-PXZ or mCBP-BP-PXZ is 2.3 eV, and the absorption band gap width (gap) of Ir(MDQ)₂acac is 2.1 eV, thus using DCB-BP-PXZ, CBP-BP-PXZ, mCP-BP-PXZ or mCBP-BP-PXZ as the host material of Ir(MDQ)₂acac can effectively promote energy transfer. Therefore, using DCB-BP-PXZ, CBP-BP-PXZ, mCP-BP-PXZ or mCBP-BP-PXZ as the host material and Ir(MDQ)₂acac as the guest material can realize a red light emitting device having high efficiency and low cost.

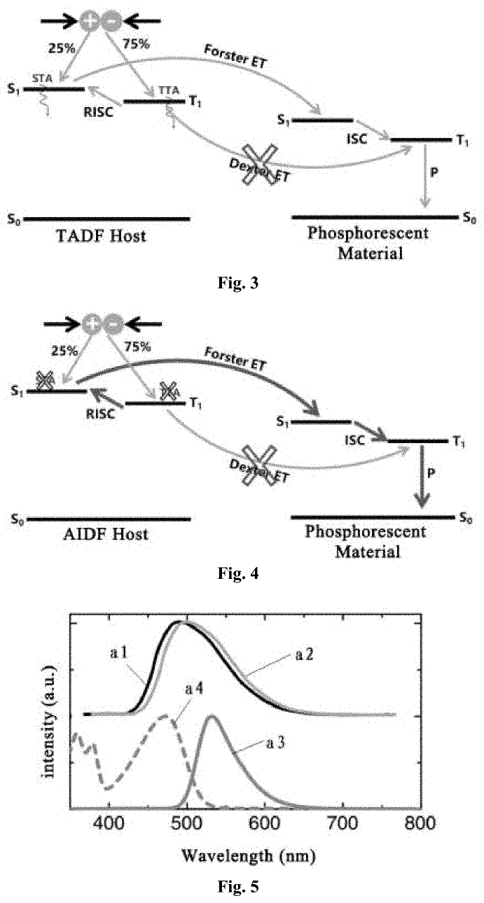

In the application process, in the light emitting layer, holes and electrons recombine and then form excitons mainly on the host material. According to the principle of spin statistics, the ratio of triplet excitons to singlet excitons produced by the recombination is 3:1, respectively. As shown in FIG. 2, in a traditional phosphorescent device, the singlet excitons formed on the traditional host material are transferred to the phosphorescent material (guest) through the long-range Forster energy transfer mechanism to form singlet excitons, and the triplet excitons formed on the traditional host material are transferred to the phosphorescent material through the short-range Dexter energy transfer mechanism to form triplet excitons, and then the single/triplet excitons finally radiate de-excitation light on the phosphorescent material. The short-range Dexter energy transfer process is more affected by the doping concentration. The lower the doping concentration, the lower the efficiency of the process. Therefore, in traditional phosphorescent devices, the doping concentration cannot be too low. As shown in FIG. 3, due to the specific electronic energy level structure, the triplet excitons on the thermally activated delayed fluorescence (TADF) host material can form singlet excitons by virtue of the upconversion in the process of the reverse intersystem crossing (RISC). If the TADF material is used as the host material of the phosphorescent material (guest), the triplet excitons formed on the host material can form singlet excitons by virtue of the upconversion and then energy is transferred to the phosphorescent guest material through Forster mechanism, there is no need to transfer energy through Dexter mechanism. Therefore, the doping concentration of the phosphorescent material can be reduced, thereby reducing the cost. The phosphorescent device having TADF material as the host material reduces the doping concentration and maintaining the same level of efficiency at the same time. However, there will be a certain annihilation process for excitons on the TADF host material (triplet-triplet exciton annihilation (TTA) or singlet-triplet exciton annihilation (STA)), and the efficiency is not high. As shown in FIG. 4, in the present disclosure, AIDF material is used as the host material and a phosphorescent material is used as the light emitting guest. In the light emitting device (OLED device), the triplet excitons formed on the AIDF host can form a singlet excitation by virtue of the upconversion and then energy is transferred to the phosphorescent material through Forster mechanism, and there is no need to transfer energy through Dexter mechanism. Thus, the doping concentration can be reduced to less than 1%, thereby reducing the cost; at the same time, the exciton annihilation process (TTA or STA) on the host can be inhibited, thereby improving the efficiency. Therefore, the new light emitting device can have the advantages of low cost and high efficiency, and thus has great application potential.

According to some embodiments of the present disclosure, the host material may be CP-BP-DMAC or DBT-BZ-DMAC, and the guest material may be TTPA. Among them, CP-BP-DMAC and DBT-BZ-DMAC are green light AIDF materials, their non-doped OLED devices have a quantum efficiency of up to 15%, and the efficiency roll-off is very small, and their exciton utilization rate is high and the exciton annihilation degree is small; and TTPA is a green fluorescent material having stable molecular structure and long lifetime. As shown in FIG. 5, curve a1 represents the emission spectrum of CP-BP-DMAC, curve a2 represents the emission spectrum of DBT-BZ-DMAC, curve a3 represents the emission spectrum of TTPA, and curve a4 represents the absorption spectrum of TTPA, there is large overlap integral between the emission spectrum of CP-BP-DMAC and DBT-BZ-DMAC and the absorption spectrum of TTPA, which can effectively promote energy transfer. Therefore, sensitizing TTPA through CP-BP-DMAC or DBT-BZ-DMAC can achieve a green light emitting device having high efficiency and long lifetime.

According to other embodiments of the present disclosure, the host material may be PCZ-CB-TRZ or TPA-CB-TRZ, and the guest material may be DBP. Among them, PCZ-CB-TRZ or TPA-CB-TRZ is orange AIDF material, its non-doped OLED device has a quantum efficiency up to 11%, and the efficiency roll-off is very small, and its exciton utilization rate is high and the exciton annihilation degree is small; and DBP is a red fluorescent material having stable molecular structure and long lifetime. As shown in FIG. 7, curve c1 represents the emission spectrum of PCZ-CB-TRZ, curve c2 represents the emission spectrum of TPA-CB-TRZ, curve c3 represents the emission spectrum of DBP, and curve c4 represents the absorption spectrum of DBP. There is a large overlap integral between the emission spectra of PCZ-CB-TRZ and TPA-CB-TRZ and the absorption spectrum of DBP, which can effectively promote energy transfer. Therefore, sensitizing DBP through PCZ-CB-TRZ or TPA-CB-TRZ can achieve a red light emitting device having high efficiency and long lifetime.

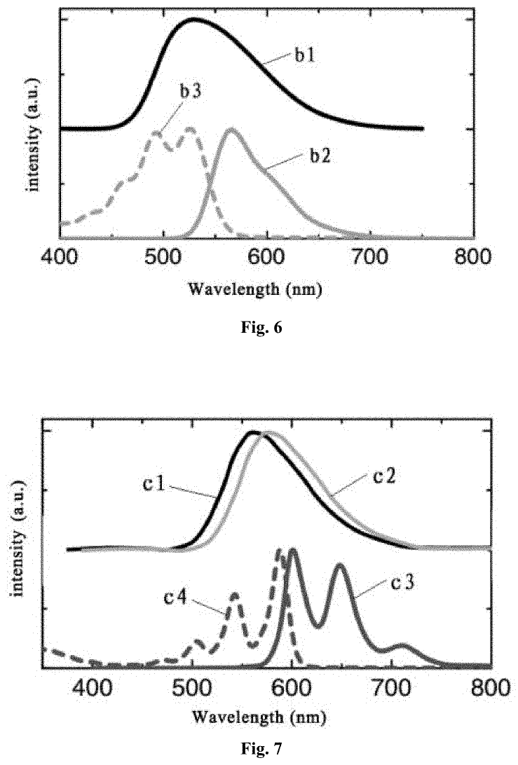

In an embodiment of the present disclosure, the host material may be DCB-BP-PXZ, CBP-BP-PXZ, mCP-BP-PXZ or mCBP-BP-PXZ, and the guest material may be TBRb. Among them, DCB-BP-PXZ, CBP-BP-PXZ, mCP-BP-PXZ or mCBP-BP-PXZ are green AIDF materials, their non-doped OLED devices have a quantum efficiency of up to 22%, the efficiency roll-off is very small, and their exciton utilization rate is high and the exciton annihilation degree is small; and TBRb is a yellow fluorescent material having stable molecular structure and long lifetime. As shown in FIG. 6, the emission spectra of DCB-BP-PXZ, CBP-BP-PXZ, mCP-BP-PXZ and mCBP-PXZ are roughly as shown in curve b1, curve b2 represents the emission spectrum of TBRb, and curve b3 represents the absorption spectrum of TBRb. There is a large overlap integral between the emission spectra of DCB-BP-PXZ, CBP-BP-PXZ, mCP-BP-PXZ and mCBP-BP-PXZ and the absorption spectrum of TBRb, which can effectively promote energy transfer. Therefore, sensitizing TBRb through DCB-BP-PXZ, CBP-BP-PXZ, mCP-BP-PXZ or mCBP-BP-PXZ can achieve a yellow light emitting device having high efficiency and long lifetime.

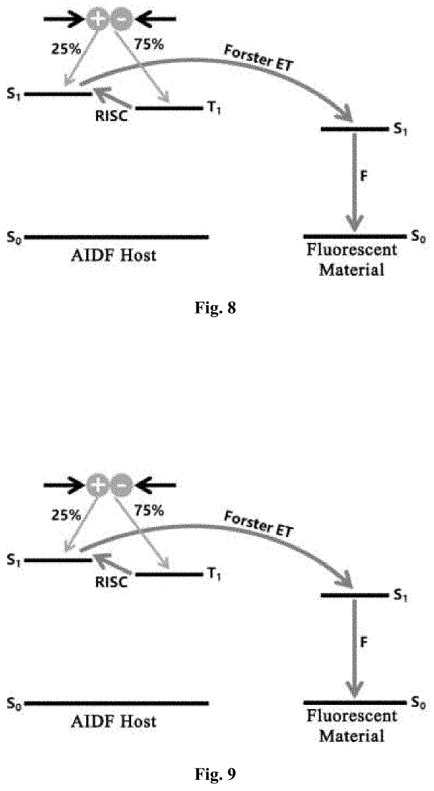

In the application process, the thermally activated delayed fluorescence (TADF) material can also realize the simultaneous utilization of triplet and singlet excitons by virtue of the reverse intersystem crossing process. The corresponding OLED device has a high exciton utilization rate, and this type of material does not contain precious metal elements and thus has low synthesis cost. As shown in FIG. 8, TADF material can be used as the host or auxiliary host to sensitize the fluorescent material (guest), and excitons will be annihilated to a certain extent (TTA or STA) on the TADF host or auxiliary host, and the efficiency will be reduced. AIDF material can use triplet and singlet excitons at the same time, in which the intermolecular force is weak, the molecular structure of traditional fluorescent materials is stable, AIDF-OLED has high efficiency, low exciton annihilation, and long lifetime. In this disclosure, AIDF material is used as the host material to sensitize the fluorescent material (guest). In this type of light emitting device structure, as shown in FIG. 9, the triplet and singlet excitons formed by the recombination can be completely absorbed on the host AIDF material and efficiently sensitize stable fluorescent guest materials, and the exciton annihilation process (TTA or STA) on the host can be inhibited and achieve the advantages of high efficiency and long lifetime at the same time, and thus it has huge application potential.

In some embodiments of the present disclosure, as shown in FIG. 1a, the light emitting device may further include: a hole transport layer 12 and an electron transport layer 13, in which the hole transport layer 12, the light emitting layer 10 and the electron transport layer 13 are stacked in sequence. The light emitting device may further include an anode 15 and a cathode 16, in which the anode 15, the hole transport layer 12, the light emitting layer 10, the electron transport layer 13, and the cathode 16 may be stacked in sequence, and in which the anode 15 or the cathode 16 may be arranged on the substrate. As shown in FIG. 1b, the light emitting device may further include: a hole injection layer 11 and an electron injection layer 14, in which the hole injection layer 11, the hole transport layer 12, the light emitting layer 10, the electron transport layer 13, and the electron injection layer 14 are stacked in sequence. In the application process, the light emitting device can be arranged to be an upright or inverted device according to needs.

The advantageous effects of the above technical solutions of the present disclosure are shown as follows.

According to the light emitting device of the embodiment of the present disclosure, the light emitting layer has a host material and a guest material, in which the host material includes an aggregation-induced delayed fluorescent material, and the guest material includes at least one of a fluorescent material and/or a phosphorescent material. In the light emitting device of the present disclosure, the aggregation-induced delayed fluorescent material is used as the host material, at least one of the fluorescent material and/or phosphorescent material is used as the doped light emitting material, and the triplet excitons on the aggregation-induced delayed fluorescent material can form singlet excitons by virtue of the conversion in the process of the reverse intersystem crossing. At the same time, due to the weak intermolecular force thereof, the aggregation-induced delayed fluorescent material can effectively inhibit the exciton annihilation process, improve the luminous efficiency, prolong the lifetime, and reduce the cost.

An embodiment of the present disclosure provides a display substrate, including the light emitting device as described in the above embodiment. The display substrate having the light emitting device in the above embodiment has advantages of high luminous efficiency, long lifetime, and low cost.

An embodiment of the present disclosure provides a display equipment, including the display substrate as described in the above embodiment. The display equipment having the display substrate in the above embodiment has advantages of high luminous efficiency, long lifetime, and low cost.

Unless otherwise defined, technical terms or scientific terms used herein have the normal meaning commonly understood by one skilled in the field of the present disclosure. The words “first”, “second”, and the like used herein do not denote any order, quantity, or importance, but rather merely serve to distinguish different components. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

The above description is alternative embodiments of the present disclosure. It should be noted that one skilled in the art would make several improvements and substitutions without departing from the principles of the present disclosure. These improvements and modifications should also be regarded as the protection scope of the present disclosure.

What is claimed is:

1. A light emitting device, comprising:
a light emitting layer, the light emitting layer comprising a host material comprising an aggregation-induced delayed fluorescent material and a guest material comprising at least one of a fluorescent material or a phosphorescent material.

2. The light emitting device of claim 1, wherein an emission spectrum of the host material at least partially overlaps an absorption spectrum of the guest material.

3. The light emitting device of claim 1, wherein a content of the guest material is in a range from 0.3% to 1% of a sum of masses of the host material and the guest material.

4. The light emitting device of claim 1, wherein
the host material comprises at least one of CP-BP-DMAC, DBT-BZ-DMAC, DCB-BP-PXZ, CBP-BP-PXZ, mCP-BP-PXZ, mCBP-BP-PXZ, PCZ-CB-TRZ or TPA-CB-TRZ; and
the guest material comprises: at least one of Ir(ppy)₃, PO-1, Ir(MDQ)₂acac, TTPA, TBRb or DBP;
wherein CP-BP-DMAC has a structural formula of: 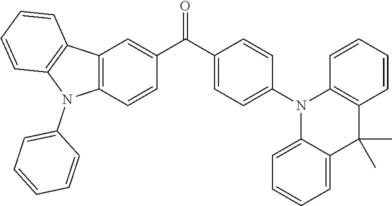 [SMILES: CC1(C)c2ccccc2N(c2ccc(C(=O)c3ccc4c(c3)c3ccccc3n4-c3ccccc3)cc2)c2ccccc21]
DBT-BZ-DMAC has a structural formula of: 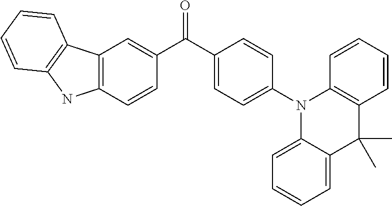 [SMILES: CC1(C)c2ccccc2N(c2ccc(C(=O)c3ccc4[nH]c5ccccc5c4c3)cc2)c2ccccc21]
DCB-BP-PXZ has a structural formula of: 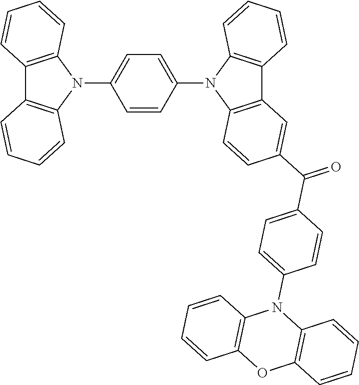 [SMILES: O=C(c1ccc(N2c3ccccc3Oc3ccccc32)cc1)c1ccc2c(c1)c1ccccc1n2-c1ccc(-n2c3ccccc3c3ccccc32)cc1]
DCB-BP-PXZ has a structural formula of: 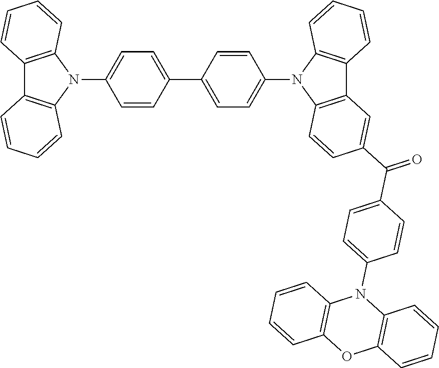 [SMILES: O=C(c1ccc(N2c3ccccc3Oc3ccccc32)cc1)c1ccc2c(c1)c1ccccc1n2-c1ccc(-c2ccc(-n3c4ccccc4c4ccccc43)cc2)cc1]
mCP-BP-PXZ has a structural formula of: 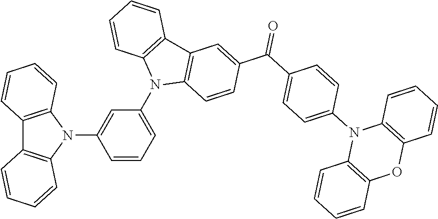 [SMILES: O=C(c1ccc(N2c3ccccc3Oc3ccccc32)cc1)c1ccc2c(c1)c1ccccc1n2-c1cccc(-n2c3ccccc3c3ccccc32)c1]
mCBP-BP-PXZ has a structural formula of: 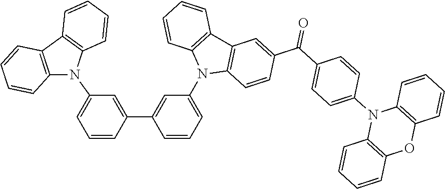 [SMILES: O=C(c1ccc(N2c3ccccc3Oc3ccccc32)cc1)c1ccc2c(c1)c1ccccc1n2-c1cccc(-c2cccc(-n3c4ccccc4c4ccccc43)c2)c1]
PCZ-CB-TRZ has a structural formula of: 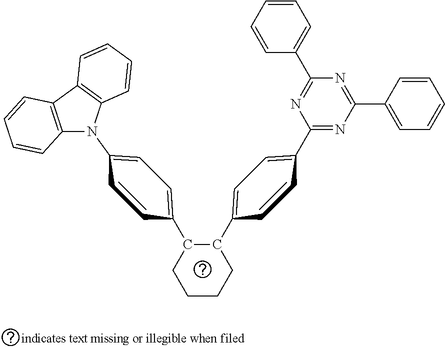
TPA-CB-TRZ has a structural formula of: 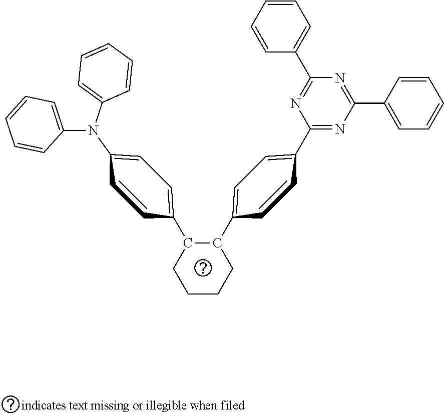
Ir(ppy)₃ has a structural formula of: 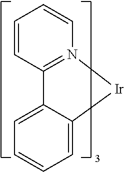
PO-1 has a structural formula of: 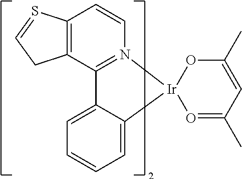
Ir(MDQ)₂acac has a structural formula of: 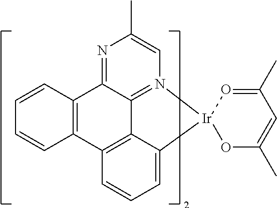
TTPA has a structural formula of: 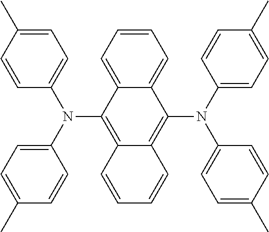 [SMILES: Cc1ccc(N(c2ccc(C)cc2)c2c3ccccc3c(N(c3ccc(C)cc3)c3ccc(C)cc3)c3ccccc23)cc1]
TBRb has a structural formula of: 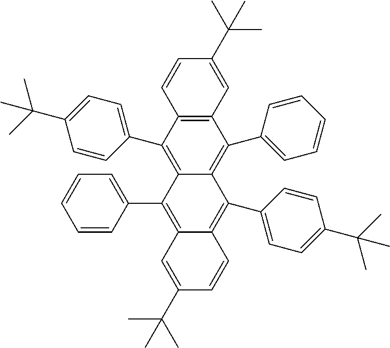 [SMILES: CC(C)(C)c1ccc(-c2c3ccc(C(C)(C)C)cc3c(-c3ccccc3)c3c(-c4ccc(C(C)(C)C)cc4)c4ccc(C(C)(C)C)cc4c(-c4ccccc4)c23)cc1]
DBP has a structural formula of: 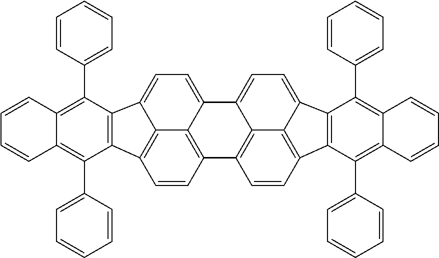 [SMILES: c1ccc(-c2c3c(c(-c4ccccc4)c4ccccc24)-c2ccc4c5ccc6c7c(ccc(c8ccc-3c2c84)c75)-c2c-6c(-c3ccccc3)c3ccccc3c2-c2ccccc2)cc1]
wherein signs “•” in the structural formulae of PCZ-CB-TRZ and TPA-CB-TRZ represent BH.

5. The light emitting device of claim 4, wherein the host material is CP-BP-DMAC or DBT-BZ-DMAC, and the guest material is Ir(ppy)₃.

6. The light emitting device of claim 4, wherein the host material is CP-BP-DMAC or DBT-BZ-DMAC, and the guest material is PO-1.

7. The light emitting device of claim 4, wherein the host material is DCB-BP-PXZ, CBP-BP-PXZ, mCP-BP-PXZ or mCBP-BP-PXZ, and the guest material is Ir(MDQ)₂acac.

8. The light emitting device of claim 4, wherein the host material is CP-BP-DMAC or DBT-BZ-DMAC, and the guest material is TTPA.

9. The light emitting device of claim 4, wherein the host material is PCZ-CB-TRZ or TPA-CB-TRZ, and the guest material is DBP.

10. The light emitting device of claim 4, wherein the host material is DCB-BP-PXZ, CBP-BP-PXZ, mCP-BP-PXZ or mCBP-BP-PXZ, and the guest material is TBRb.

11. The light emitting device of claim 1, wherein the light emitting device further comprises:
a hole transport layer and an electron transport layer, wherein the hole transport layer, the light emitting layer, and the electron transport layer are stacked in sequence.

12. The light emitting device of claim 11, wherein the light emitting device further comprises:
a hole injection layer and an electron injection layer, wherein the hole injection layer, the hole transport layer, the light emitting layer, the electron transport layer, and the electron injection layer are stacked in sequence.

13. The light emitting device of claim 11, wherein the light emitting device further comprises:
an anode and a cathode, wherein the anode, the hole transport layer, the light emitting layer, the electron transport layer, and the cathode are stacked in sequence.

14. A display substrate, comprising the light emitting device of claim 1.

15. A display equipment, comprising the display substrate of claim 14.
